(19) United States
(12) Patent Application Publication
(10) Pub. No.: US 2026/0178787 A1
(43) Pub. Date: Jun. 25, 2026

(54) SYSTEM AND METHOD FOR MANAGEMENT OF VEHICLE SOFTWARE DESIGN MATERIAL

(71) Applicant: TOYOTA JIDOSHA KABUSHIKI KAISHA, Toyota-shi (JP)

(72) Inventors: Peter BERGER, Tokyo (JP); Jean-François BASTIEN, Tokyo (JP); Jean-Francois CAMPEAU, Tokyo (JP); Yoshiya HATTORI, Nagoya-shi (JP); Kentaro SHIOTA, Urayasu-shi (JP)

(73) Assignee: TOYOTA JIDOSHA KABUSHIKI KAISHA, Toyota-shi (JP)

(21) Appl. No.: 18/987,192

(22) Filed: Dec. 19, 2024

(51) Int. Cl. G06F 30/15

(52) U.S. Cl. CPC G06F 30/15

(57) ABSTRACT

Provided are system, method, and device for automatically managing vehicle software design materials. According to example embodiments, the system may include: a memory storage storing computer-executable instructions; and at least one processor communicatively coupled to the memory storage, wherein the at least one processor may be configured to execute the instructions to: obtain a plurality of vehicle design materials; extract information from the plurality of vehicle design materials; and generate a vehicle software development plan based on the extracted information, wherein the vehicle software development plan may include a plurality of design levels defining a plan for designing a vehicle software at a plurality of levels.

### TECHNICAL FIELD

Example embodiments of the present disclosure relate to a vehicle software design, and more specifically, relate to the management of materials used in the design and development of a vehicle software.

### BACKGROUND

Modern vehicles are capable of performing a wide range of complex functions, such as generating telemetry data, transmitting and receiving data via the internet, and the like. In this regard, vehicle software design is a crucial part of the planning and development process for such vehicles.

In general, the vehicle software design process involves a collection of isolated reference materials that are referred to before the beginning of vehicle software design process. These materials include, for example, system requirement specifications (SRS), data sheets, and the like, and may be in the form of written papers, roadmaps, presentation slides, specifications, data stores, and the like. Further, these materials are created and delivered to suppliers before the beginning of vehicle software design process.

### SUMMARY

Example embodiments consistent with the present disclosure allow for integration of reference materials into vehicle software design process, which subsequently allows for improvement in organization and management of the reference materials as well as improvement in effectiveness and quality of the vehicle software resulting from such vehicle software design process.

According to example embodiments, a system is provided. The system may include: a memory storage storing computer-executable instructions; and at least one processor communicatively coupled to the memory storage, wherein the at least one processor may be configured to execute the instructions to: obtain a plurality of vehicle design materials; extract information from the plurality of vehicle design materials; and generate a vehicle software development plan based on the extracted information, wherein the vehicle software development plan may include a plurality of design levels defining a plan for designing a vehicle software at a plurality of levels.

According to example embodiments, the at least one processor may be configured to execute the instructions to extract information from the plurality of vehicle design materials by processing the plurality of vehicle design materials into an ontology of domain specific language.

According to example embodiments, the plurality of design levels may include: a first level defining a system of interest; a second level defining a vehicle within the system of interest; a third level defining a sub-system within the vehicle; a fourth level defining hardware and software compositions within the sub-system; a fifth level defining a component within the hardware and software compositions; and a sixth level defining a sub-component within the component.

According to example embodiments, the plurality of vehicle design materials may include a system requirement specification (SRS).

According to example embodiments, the at least one processor may be configured to execute the instructions to store the extracted information in a single source of truth (SSOT) database.

According to example embodiments, the at least one processor may be configured to execute the instructions to generate a graphical user interface (GUI) based on the vehicle software development plan, wherein the GUI may show interrelationships between a plurality of elements of the plurality of design levels across the plurality of design levels and interrelationships between the plurality of elements of the plurality of design levels within a respective level of the plurality of design levels.

According to example embodiments, the at least one processor may be configured to execute the instructions to transmit data associated with the vehicle software development plan to a system for testing and validation of the vehicle software.

According to example embodiments, a method is provided. The method may include: obtaining a plurality of vehicle design materials; extracting information from the plurality of vehicle design materials; and generating a vehicle software development plan based on the extracted information, wherein the vehicle software development plan may include a plurality of design levels defining a plan for designing a vehicle software at a plurality of levels.

According to example embodiments, the extracting information from the plurality of vehicle design materials may include processing the plurality of vehicle design materials into an ontology of domain specific language.

According to example embodiments, the plurality of design levels may include: a first level defining a system of interest; a second level defining a vehicle within the system of interest; a third level defining a sub-system within the vehicle; a fourth level defining hardware and software compositions within the sub-system; a fifth level defining a component within the hardware and software compositions; and a sixth level defining a sub-component within the component.

According to example embodiments, the plurality of vehicle design materials may include a system requirement specification (SRS).

According to example embodiments, the method may further include storing the extracted information in a single source of truth (SSOT) database.

According to example embodiments, the method may further include generating a graphical user interface (GUI) based on the vehicle software development plan, wherein the GUI may show interrelationships between a plurality of elements of the plurality of design levels across the plurality of design levels and interrelationships between the plurality of elements of the plurality of design levels within a respective level of the plurality of design levels.

According to example embodiments, the method may further include transmitting data associated with the vehicle software development plan to a system for testing and validation of the vehicle software.

According to example embodiments, a non-transitory computer-readable recording medium is provided. The non-transitory computer-readable recording medium may have recorded thereon instructions executable by at least one processor to cause the at least one processor to perform a method including: obtaining a plurality of vehicle design materials; extracting information from the plurality of vehicle design materials; and generating a vehicle software development plan based on the extracted information, wherein the vehicle software development plan may include a plurality of design levels defining a plan for designing a vehicle software at a plurality of levels.

According to example embodiments, the extracting information from the plurality of vehicle design materials may include processing the plurality of vehicle design materials into an ontology of domain specific language.

According to example embodiments, the plurality of design levels may include: a first level defining a system of interest; a second level defining a vehicle within the system of interest; a third level defining a sub-system within the vehicle; a fourth level defining hardware and software compositions within the sub-system; a fifth level defining a component within the hardware and software compositions; and a sixth level defining a sub-component within the component.

According to example embodiments, the plurality of vehicle design materials may include a system requirement specification (SRS).

According to example embodiments, the method may further include storing the extracted information in a single source of truth (SSOT) database.

According to example embodiments, the method may further include generating a graphical user interface (GUI) based on the vehicle software development plan, wherein the GUI may show interrelationships between a plurality of elements of the plurality of design levels across the plurality of design levels and interrelationships between the plurality of elements of the plurality of design levels within a respective level of the plurality of design levels.

Additional aspects will be set forth in part in the description that follows and, in part, will be apparent from the description, or may be realized by practice of the presented embodiments of the disclosure.

### BRIEF DESCRIPTION OF THE DRAWINGS

Features, advantages, and significance of exemplary embodiments of the disclosure will be described below with reference to the accompanying drawings, in which like reference numerals denote like elements, and wherein:

FIG. 1 illustrates a block diagram of an example system configuration for managing vehicle software design material, according to one or more example embodiments;

FIG. 2 illustrates a flow diagram of an example method for managing vehicle software design material, according to one or more example embodiments;

FIG. 3 illustrates example components of a single source of truth (SSOT) database, according to one or more example embodiments;

FIG. 4A to FIG. 4F illustrate an example vehicle software development plan, according to one or more example embodiments;

FIG. 5 illustrates an example graphical user interface (GUI), according to one or more example embodiments; and

FIG. 6 illustrates a block diagram of example components in a system, according to one or more example embodiments.

### DETAILED DESCRIPTION

The following detailed description of exemplary embodiments refers to the accompanying drawings. The foregoing disclosure provides illustration and description but is not intended to be exhaustive or to limit the implementations to the precise form disclosed. Modifications and variations are possible in light of the above disclosure or may be acquired from practice of the implementations. Further, one or more features or components of one embodiment may be incorporated into or combined with another embodiment (or one or more features of another embodiment). Additionally, in the flowcharts and descriptions of operations provided below, it is understood that one or more operations may be omitted, one or more operations may be added, one or more operations may be performed simultaneously (at least in part), and the order of one or more operations may be switched.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Where only one item is intended, the term “one” or similar language is used. Also, as used herein, the terms “has,” “have,” “having,” “include,” “including,” or the like are intended to be open-ended terms. Further, the phrase “based on” is intended to mean “based, at least in part, on” unless explicitly stated otherwise. Furthermore, expressions such as “[A] and/or [B]”, “at least one of [A] and [B]” or “at least one of [A] or [B]” are to be understood as including only A, only B, or both A and B.

Expressions such as “at least one processor,” where configured to implement a plurality of operations, execute a plurality of instructions, etc., are to be understood as a single processor implementing the plurality of operations, etc., or each of plural processors implementing at least some (but not necessarily all) of the plurality of operations, etc.

Reference throughout this specification to “one embodiment,” “an embodiment,” “non-limiting exemplary embodiment,” or similar language means that a particular feature, structure, or characteristic described in connection with the indicated embodiment is included in at least one embodiment of the present solution. Thus, the phrases “in one embodiment”, “in an embodiment,” “in one non-limiting exemplary embodiment,” and similar language throughout this specification may, but do not necessarily, all refer to the same embodiment.

Further, the described features, advantages, and characteristics of the present disclosure may be combined in any suitable manner in one or more example embodiments. One skilled in the relevant art will recognize, in light of the description herein, that the present disclosure can be practiced without one or more of the specific features or advantages of a particular embodiment. In other instances, additional features and advantages may be recognized in certain embodiments that may not be present in all embodiments of the present disclosure.

Furthermore, the term “vehicle” described herein refers to any suitable type of vehicle in which example embodiments of the present disclosure can be implemented. For instance, the “vehicle” may refer to a motorized vehicle such as a car, a truck, a bus, a motorcycle, or any other suitable type of automobile powered by an engine, motor, or other mechanical means. Alternatively or additionally, the “vehicle” described herein may refer to a bicycle, a skateboard, and any other suitable types of non-motorized vehicle, without departing from the scope of the present disclosure.

As explained above, the vehicle software design process involves the reference materials that are referred to before the beginning of vehicle software design process. In this regard, since the materials are simply referred to before the beginning of vehicle software design process, the materials are not directly integrated and utilized in the vehicle software design process itself.

This prevents integration of the materials into the initial and on-going builds of the vehicle software being developed/designed in the software design process, as well as into the Continuous Development/Continuous Integration (CICD) software development environment in the software design process. Such lack of integration can impact production and validation of vehicle software, as well as supply chain management and security. Accordingly, there is a need for a system that allows for the materials to be properly integrated into the vehicle software design process itself.

It is contemplated that features, advantages, and significances of example embodiments described herein are merely a portion of the present disclosure, and are not intended to be exhaustive or to limit the scope of the present disclosure. Further descriptions of the features, components, configuration, operations, and implementations of the example embodiments of the present disclosure are provided in the following.

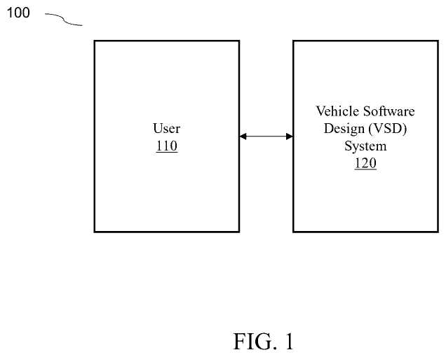

FIG. 1 illustrates a block diagram of an example system configuration 100 for managing vehicle software design material, according to one or more example embodiments. As illustrated in FIG. 1, system configuration 100 may include a User 110 and a Vehicle Software Design (VSD) system 120.

The user 110 may include entities, such as software developers, project managers, vendors, stakeholders, original equipment manufacturers (OEMs), and the like that are involved in the vehicle software design process. According to example embodiments, the user 110 may provide vehicle design materials to the VSD system 120 for use in the development and design of a vehicle software (i.e., vehicle software design process), and may receive information related to the development and design of the vehicle software (e.g., vehicle software development plan) from the VSD system 120.

The VSD system 120 may include an apparatus, a system, a platform, a module, or the like, which may be configured to perform one or more operations or actions for managing vehicle software design material. According to example embodiments, the VSD system 120 may be communicatively coupled to a separate system that is involved in the vehicle software design process. For example, the VSD system may be communicatively coupled to a testing system that is configured to perform operations related to validations and testing of a vehicle software. According to example embodiments, the VSD system 120 may be combined with or be part of a system that is involved in the vehicle software design process. For example, the VSD system may be part of the testing system.

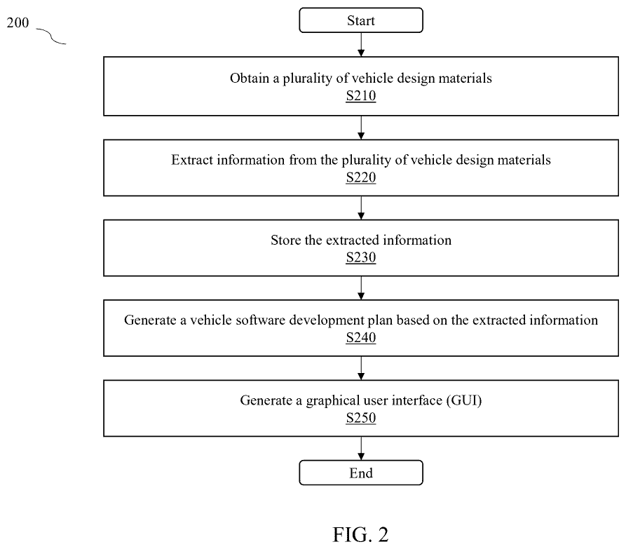

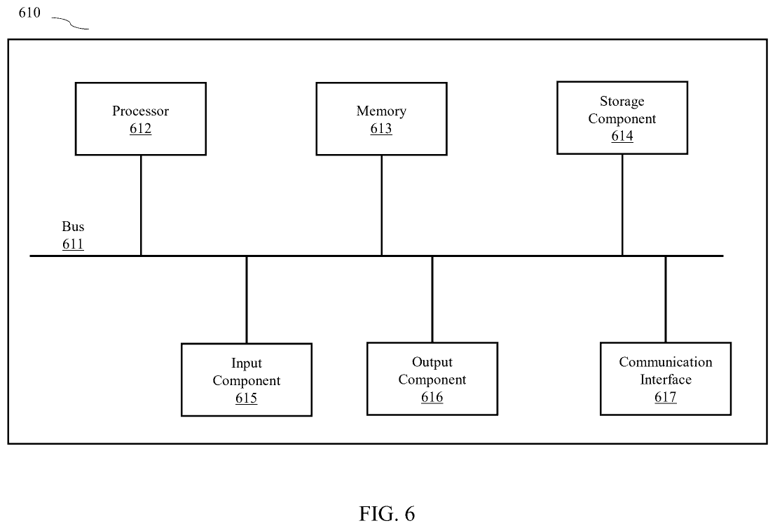

Example operations performable by the VSD system 120 for managing vehicle software design material are described below with reference to FIG. 2 to FIG. 5. Further, several example components which may be included in the VSD system 120, according to one or more example embodiments, are described below with reference to FIG. 6.

In the following, several example operations performable by the VSD system of the present disclosure are described with reference to FIG. 2 to FIG. 5.

FIG. 2 illustrates a flow diagram of an example method 200 for managing vehicle software design material, according to one or more example embodiments. One or more operations in method 200 may be performed by at least one processor (e.g., processor 612 described below) of a Vehicle Software Design (VSD) system.

As illustrated in FIG. 2, at operation S210, the at least one processor may be configured to obtain a plurality of vehicle design materials. The plurality of vehicle design materials may be obtained from a user, and may include materials used in the vehicle software design process. For example, the materials may include system requirement specifications (SRS), product requirement documents (PRD), data sheets, written papers, roadmaps, presentation slides, data stores, value streams, and the like. The method then proceeds to operation S220.

At operation S220, the at least one processor may be configured to extract information from the plurality of vehicle design materials.

According to example embodiments, the information may be extracted by processing the plurality of vehicle design materials into an ontology of domain specific language. In particular, the plurality of vehicle design materials may be parsed and normalized into a plurality of languages. Each of the plurality of languages may be specific to a design level (i.e., domain) of a plurality of design levels in a vehicle software development plan (see additional description below in relation to operation S240). The method then proceeds to operation S230.

At operation S230, the at least one processor may be configured to store the extracted information. The extracted information may be stored in a single source of truth (SSOT) database.

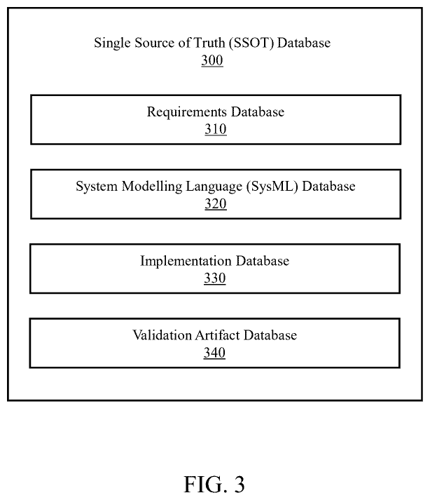

FIG. 3 illustrates example components of a single source of truth (SSOT) database 300, according to one or more example embodiments. As shown in FIG. 3, the SSOT database 300 may include at least a requirement database 310, a system modelling language (SysML) database 320, an implementation database 330, and a validation artifact database 340, although it is understood that the SSOT database 300 may include more or less components without departure from the scope of the present disclosure.

The requirement database 310 may be configured to store data related to requirements of the extracted information. The SysML database 320 may be configured to store the extracted information in a system modelling language (SysML) format. The implementation database 330 may be configured to store data related to implementations of the extracted information. The validation artifact database 340 may be configured to store data related to validation and artifacts of the extracted information.

Here, it is understood that the data related to requirements of the extracted information, data related to implementations of the extracted information, data related to validation and artifacts of the extracted information, and the extracted information in the SysML format may be obtained as outputs from parsing and normalizing the plurality of vehicle design materials.

According to example embodiments, the requirement database 310, system modelling language (SysML) database 320, implementation database 330, and validation artifact database 340 may be synchronized with each other. The method then proceeds to operation S240.

At operation S240, the at least one processor may be configured to generate a vehicle software development plan. The vehicle software development plan may be generated based on the extracted information, and may include a plurality of design levels defining a plan for designing the vehicle software at a plurality of levels.

According to example embodiments, the plurality of design levels may include: a first level defining a system of interest; a second level defining a vehicle within the system of interest; a third level defining a sub-system within the vehicle; a fourth level defining hardware and software compositions within the sub-system; a fifth level defining a component within the hardware and software compositions; and a sixth level defining a sub-component within the component.

For example, the first level may define a connected vehicle ecosystem that comprises a plurality of vehicles, cloud networks, mobile devices, and the like, and the second level may define a specific vehicle within such eco system. The third level may then define all sub-systems within such vehicle, such as various electronics control units (ECUs) (e.g., central ECU, advanced driver assistance system (ADAS) ECU, in-vehicle infotainment (IVI) ECU, and the like), power train, chassis, body, and the like. The fourth level may then define all hardware and software compositions related to each of the sub-systems. For example, the fourth level may define hardware and software compositions associated with the ADAS ECU, hardware and software compositions associated with the central ECU, and the like (e.g., sensors, etc.) The fifth level may then define all components associated with each of the hardware and software compositions. For example, the fifth level may define a plurality of system on chips (SoCs) associated with the hardware of the central ECU and define a plurality of applications associated with the software of the central ECU. The sixth level may then define all sub-components with each of the components. For example, the sixth level may define a plurality of cores in each of the SoCs and define a plurality of software sub-components in each of the applications.

According to example embodiments, each of the plurality of design levels may also be associated with an objective, an input, and an output. The objective may define a high level description of objective and goal of a respective design level. The input may define an input which a respective design level receives. The output may define an output and a key outcome which a respective design level provides. According to example embodiments, the output may also be defined as a requirement and an architecture of a respective level.

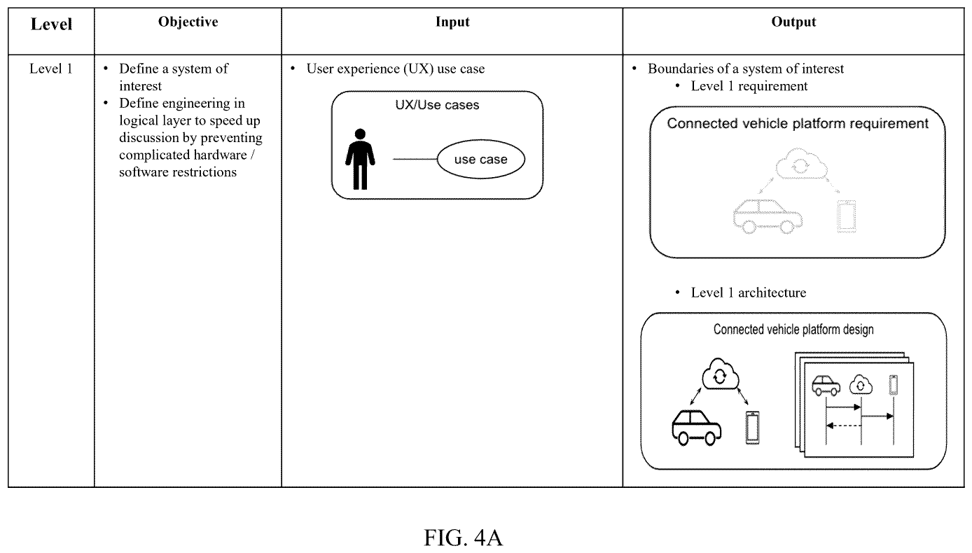

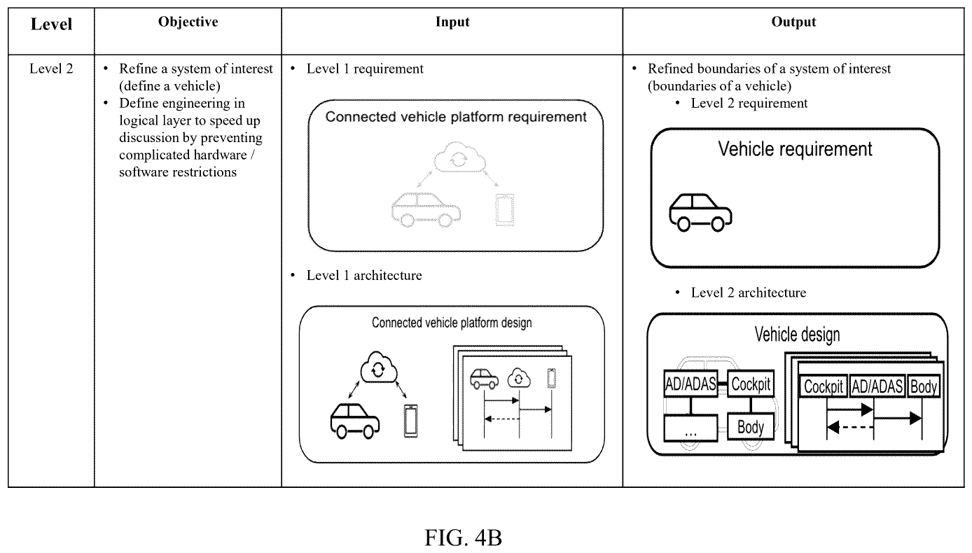

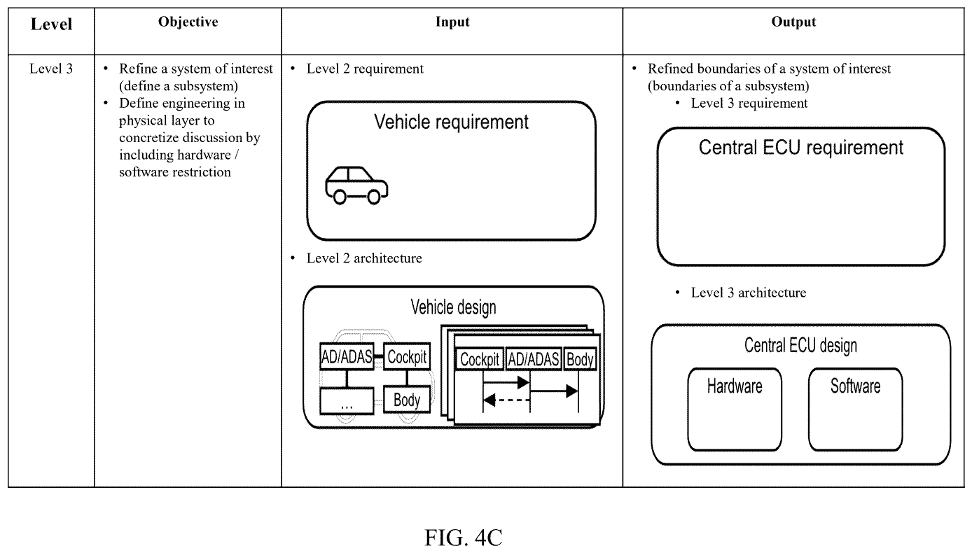

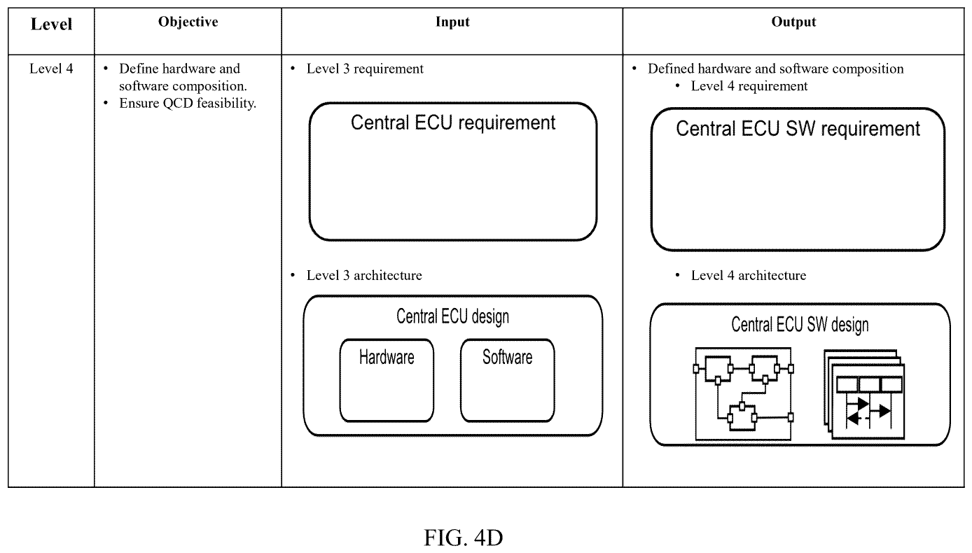

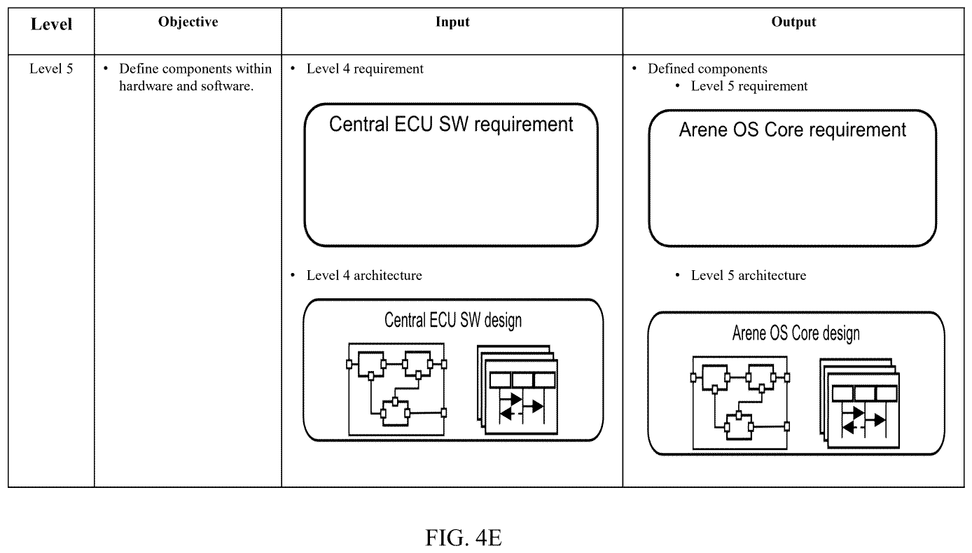

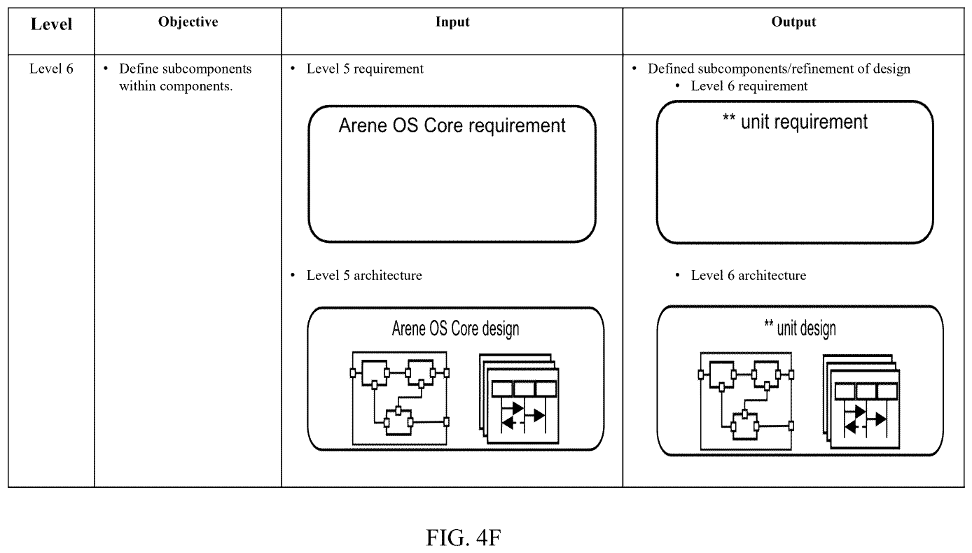

FIG. 4A to FIG. 4F illustrate an example vehicle software development plan, according to one or more example embodiments. As shown in FIG. 4A to FIG. 4F, the vehicle software development plan may include six design levels: a first level, second level, third level, fourth level, fifth level, and sixth level, although it is understood that the vehicle software development plan may include more or less design levels without departure from the scope of the present disclosure. Further, while FIG. 4A to FIG. 4F show the vehicle software development plan in the form of a table, it is understood that the vehicle software development plan is not limited to any particular form and can be defined in any form.

As shown in FIG. 4A, the first level in the vehicle software development plan may be associated with an objective, which specifies the objective of the first level as defining the system of interest and defining engineering in logical layer to speed up discussion by preventing complicated hardware/software restrictions.

The first level may also be associated with an input, which specifies the input of the first level as a user experience (UX) use case.

The first level may also be associated with an output, which specifies the output of the first level as boundaries of the system of interest. Further, the boundaries of the system of interest may be defined as a requirement of the first level as well as an architecture of the first level. For example, as shown in FIG. 4A, if the system of interest is a connected vehicle platform (ecosystem), the requirement of the first level may be the requirements of the connected vehicle platform, and the architecture of the first level may be the architecture of the connected vehicle platform (i.e., designs of the connected vehicle platform, various elements within the connected vehicle platform, relationships and communications between the elements within the connected vehicle platform, and the like). It is understood that the boundaries of the system of interest may be defined as the requirement explicitly, or system context implicitly.

As shown in FIG. 4B, the second level in the vehicle software development plan may be associated with an objective, which specifies the objective of the second level as refining the system of interest and defining engineering in logical layer to speed up discussion by preventing complicated hardware/software restrictions. Here, it is understood that refining of the system of interest may refer to defining a vehicle within the system of interest.

The second level may also be associated with an input, which specifies the input of the second level as the requirement and architecture of the first level.

The second level may also be associated with an output, which specifies the output of the second level as refined boundaries of the system of interest (i.e., boundaries of a vehicle within the system of interest). Further, the refined boundaries of the system of interest may be defined as a requirement of the second level as well as an architecture of the second level. For example, as shown in FIG. 4B, if the vehicle is a specific vehicle (e.g., a specific model/variants of a vehicle), the requirement of the second level may be the requirements of the specific vehicle, and the architecture of the second level may be the architecture of the specific vehicle (i.e., designs of the specific vehicle, various subsystems (ECUs, sensors, and the like) of the specific vehicle, relationships and communications between the subsystems of the specific vehicle, and the like). It is understood that the specific vehicle may be the main product for original equipment manufacturer (OEM).

As shown in FIG. 4C, the third level in the vehicle software development plan may be associated with an objective, which specifies the objective of the third level as refining the system of interest and defining engineering in physical layer to concretize discussion by including hardware / software restriction. Here, it is understood that refining of the system of interest may refer to defining a subsystem of the vehicle (e.g., an ECU).

The third level may also be associated with an input, which specifies the input of the third level as the requirement and architecture of the second level.

The third level may also be associated with an output, which specifies the output of the third level as refined boundaries of the system of interest (i.e., boundaries of a subsystem of a vehicle). Further, the refined boundaries of the system of interest may be defined as a requirement of the third level as well as an architecture of the third level. For example, as shown in FIG. 4C, if the subsystem is a central ECU, the requirement of the third level may be the requirements of the central ECU, and the architecture of the third level may be the architecture of the central ECU (i.e., designs of the central ECU, various hardware and software associated with the central ECU, relationships and communications between the hardware and software associated with the central ECU, and the like). It is understood that the boundaries of the subsystem may be defined as a system domain boundary to hand over from central department to each domain system department Further, it is understood that the requirement and architecture of the third level may also be used validate system quality custom distribution (QCD) (i.e., key outcome).

Although, the above description for the third level in FIG. 4C are provided for a single subsystem (e.g., central ECU), it is understood that all subsystems within the vehicle (i.e., all specific ECUs, sensors, and the like in the specific vehicle) may also be specified in the third level.

Further, it is understood that the first level, second level, and third level may act as strategic layers (levels).

As shown in FIG. 4D, the fourth level in the vehicle software development plan may be associated with an objective, which specifies the objective of the fourth level as defining hardware and software compositions of a subsystem, and ensuring QCD feasibility. It is understood that the QCD feasibility should be ensured at the fourth level, since the fourth level has a major impact on quality (including technical features), cost, and delivery date feasibility (QCD feasibility). The objective may also include a strategy to decompose a subsystem into hardware and software.

The fourth level may also be associated with an input, which specifies the input of the fourth level as the requirement and architecture of the third level.

The fourth level may also be associated with an output, which specifies the output of the fourth level as hardware and software composition. Further, the hardware and software composition may be defined as a requirement of the fourth level as well as an architecture of the fourth level. For example, as shown in FIG. 4D, if the subsystem is a central ECU which is decomposed into hardware and software compositions, the requirement of the fourth level may be the requirements of the hardware (not shown) and software compositions of the central ECU, and the architecture of the fourth level may be the architecture of the hardware (not shown) and software compositions of the central ECU (i.e., designs of the software, various applications within the software, relationships and communications between the applications within the software, and the like).

Although, the above description for the fourth level in FIG. 4D are provided for a single subsystem (e.g., central ECU), it is understood that all subsystems within the vehicle (i.e., all specific ECUs, sensors, and the like in the specific vehicle) may also be decomposed into hardware and software composition that are all specified in the fourth level.

As shown in FIG. 4E, the fifth level in the vehicle software development plan may be associated with an objective, which specifies the objective of the fifth level as defining components within the hardware and software compositions.

The fifth level may also be associated with an input, which specifies the input of the fifth level as the requirement and architecture of the fourth level.

The fifth level may also be associated with an output, which specifies the output of the fifth level as components within the hardware and software composition. Further, the components may be defined as a requirement of the fifth level as well as an architecture of the fifth level. For example, as shown in FIG. 4E, if the components in the software composition of the central ECU include an OS core application, the requirement of the fifth level may be the requirements of the OS core application, and the architecture of the fifth level may be the architecture of the OS core application (i.e., designs of the OS core application, various subcomponents within the OS core application, relationships and communications between the subcomponents within the OS core application, and the like). In another example, if the components in the hardware composition of the central ECU include an SoC, the requirement of the fifth level may be the requirements of the SoC, and the architecture of the fifth level may be the architecture of the SoC (i.e., designs of the SoC, various subcomponents within the SoC, relationships and communications between the subcomponents within the SoC, and the like).

Although, the above description for the fifth level in FIG. 4E are provided for a single subsystem (e.g., central ECU), it is understood that all subsystems within the vehicle (i.e., all specific ECUs, sensors, and the like in the specific vehicle) may also be decomposed into hardware and software composition, where all of their components may be specified in the fifth level.

As shown in FIG. 4F, the sixth level in the vehicle software development plan may be associated with an objective, which specifies the objective of the sixth level as defining subcomponents within the components. Here, it is understood that the subcomponents may be referred to as units.

The sixth level may also be associated with an input, which specifies the input of the sixth level as the requirement and architecture of the fifth level.

The sixth level may also be associated with an output, which specifies the output of the sixth level as subcomponents within the components. Further, the subcomponents may be defined as a requirement of the sixth level as well as an architecture of the sixth level. For example, as shown in FIG. 4F, the requirement of the sixth level may be the requirements of a subcomponent (unit) in the OS core application, and the architecture of the sixth level may be the architecture of a subcomponent (unit) in the OS core application (i.e., designs of the subcomponent, various sub-subcomponents within the subcomponent, relationships and communications between the sub-subcomponents within the subcomponent, and the like).

Although, the above description for the fifth level in FIG. 4F are provided for a single subsystem (e.g., central ECU), it is understood that all subsystems within the vehicle (i.e., all specific ECUs, sensors, and the like in the specific vehicle) may also be decomposed into hardware and software composition, where all of the subcomponents within their components may be specified in the sixth level.

According to example embodiments, the input and output of the plurality of design levels may be obtained by parsing and normalizing the plurality of vehicle design materials. In particular, the plurality of vehicle design materials may be normalized into a plurality of languages, where the plurality of languages may then be parsed and clustered into the plurality of design level, such that each of the plurality of languages corresponds to input and output of a respective design level in the vehicle software development plan. It is understood that the plurality of vehicle design materials may be parsed and normalized into the input and output of the plurality of design levels using any means. For example, a machine learning model and artificial intelligence may be utilized in order to parse and normalize the plurality of vehicle design materials into the input and output of the plurality of design levels. Machine learning model may include supervised learning (e.g., linear regression, k-nearest neighbor (KNN), decision tree algorithms, support machine vectors, Bayesian algorithm, ensemble algorithms, etc.), unsupervised learning (e.g., K-means clustering, principal component analysis (PCA), etc.), reinforcement learning (e.g., Q-learning, multi-armed bandit learning, deep RL, etc.), neural networks, and the like.

Accordingly, the extracted information may be organized and clustered into a plurality of design levels. Different design levels may correspond to different functional levels, which facilitate inter and cross organizational collaboration between different functional groups of original equipment manufacturer (OEM) and suppliers of software and hardware. In other words, the use of multiple design levels as described above enable multiple users (e.g., vendor, OEM stake holders, and the like) to work collaboratively. The use of multiple design levels as described above also allows for the substitution of software and hardware vendors both between but also within models and variants. The method then proceeds to operation S250.

At operation S250, the at least one processor may be configured to generate a graphical user interface (GUI). The GUI may be generated based on the vehicle software development plan. Further, the GUI may show the plurality of design levels in the vehicle software development plan, along with interrelationships between a plurality of elements of the plurality of design levels across the plurality of design levels, and interrelationships between a plurality of elements of the plurality of design levels within a respective level of the plurality of design levels. Here, the plurality of elements may refer to the subjects of each of the design levels (e.g., the subsystems in the third level, the hardware and software compositions in the fourth level, and the like).

For example, the GUI may show that a core in the sixth level is a subcomponent of an SoC in the fifth level, where the SoC in the fifth level is a component of a hardware composition in the fourth level, where the hardware composition in the fourth level is of the central ECU in the third level, where the central ECU in the third level is a subsystem of a specific vehicle in the second level, and where the specific vehicle in the second level is of a connected vehicle ecosystem in the first level.

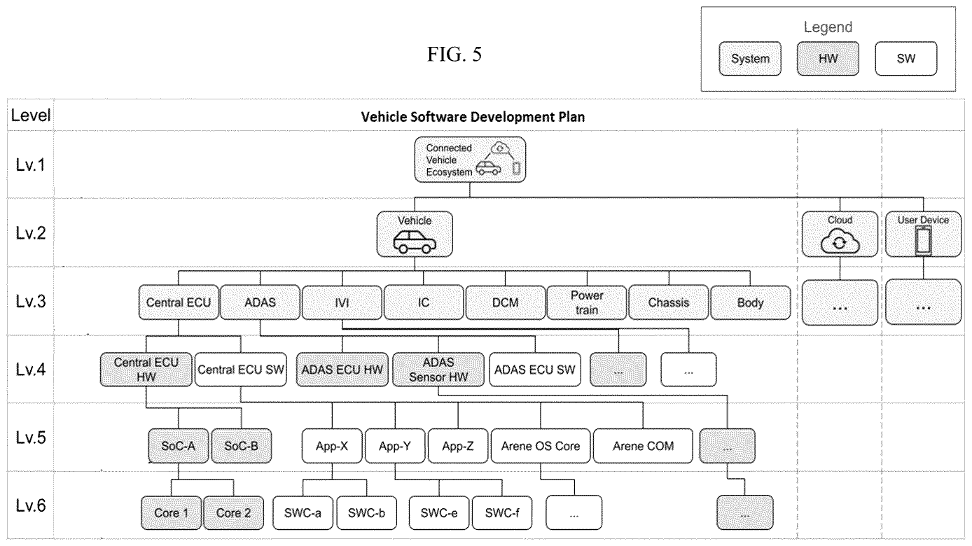

FIG. 5 illustrates an example graphical user interface (GUI), according to one or more example embodiments.

As shown in FIG. 5, the GUI shows the plurality of design levels (i.e., Lv. 1 to Lv. 6) in the vehicle software development plan, along with interrelationships between a plurality of elements of the plurality of design levels across the plurality of design levels. For example, the GUI shows the interrelationship between core 1 and core 2 in the sixth level, the SoC-A in the fifth level, the hardware composition of the central ECU in the fourth level, the central ECU in the third level, the vehicle in the second level, and the connected vehicle ecosystem in the first level.

Here, there vehicle software development plan shown with the interrelationships between the plurality of elements of the plurality of design levels may be considered as a system hierarchy tree.

Accordingly, the generated GUI may be provided to the user, which allows for visualization of the entire software design process and monitoring of the progress. The GUI may also allow for monitoring of the progress of the vehicle software design process, as well as visualizing the updates to the materials (e.g., SRS) in real-time by capturing key metrics around code commits, unit tests, and functional performance metrics in a vehicle. The GUI may also allow for cross supplier testing, cross functionality testing, real-time progression implementation of distributed teams, multi-supplier with variance management in real time that reduces software development cost timelines and increases software reusability and software update security, and measure different metrics across code bases to prioritize investment in quality and continuous improvements.

Further, as shown in the examples of design levels and GUI in FIG. 4 to FIG. 5, the architecture and requirements are tightly coupled both within the same design level and across different design levels, which allows for traceability of software changes within a design level and in between different design levels.

For example, the OEM and vendors can visualize the entire software design process, run tests on individual deliverables, run tests on multiple deliverables with unified SI Unit tests, identify reusability of software, and normalizing the management metrics to measure progress and quality.

In view of the above, the integration of materials (vehicle software design reference materials) into the vehicle software design process in the form of the interrelated design levels allows for unique design functionalities, such as capability to segregate impact analysis by levels, capability to segregate complexity by levels, reuse of code and frameworks across suppliers and vehicle variants, account for risk and liability, identification and remediation of bugs and defects in all vehicles and variants, identify, iterate, and improve the software in all vehicles and variants, and the like.

Further, the integration of materials into the vehicle software design process in the form of the interrelated design levels allows the vehicle software to be adaptable. This means that the vehicle software may be implemented based on design constraints from a single repository, rather than be implemented as a stand-alone silo. Thus, a single repository can: manage multiple variants allowing it to adapt to different signal and hardware capabilities, enable standardization of interfaces between hardware in the vehicle in service, and bridging the signals and defining metadata languages, while the architecture stays the same. The adaptable vehicle software may allow for recognition of incompatible signals between hardware, understanding of whole data of the whole system impacts, understanding of different frequency, bandwidth and modulating software, adjustments or rejection of design constraints (if signals have different ODDs).

Additionally, according to example embodiments, the VSD system may be communicatively coupled to a testing system that is configured to operations related to validations and testing of a vehicle software.

In this regard, according to example embodiments, the at least one processer may be configured to transmit data associated with the vehicle software development plan to the testing system for testing and validation of a vehicle software. The data may include at least one of software, metadata, documentation, build artifacts, and bug tractors associated with the vehicle software development plan. According to example embodiments, the at least one processer may be configured to tag the data before transmitting the data to the testing system.

The above tagging and transmitting of data associated with the vehicle software development plan to the testing system allows for segregation of IP protection for stakeholders and vendors. The above process may also enable traceability for purposes of payment of completion of software and completion of projects, ensure IP providence and attribution to facilitate Pro-Rata allocation of payments or royalties, and enable a pay-per-use royalty or microtransactions to ensure payments. The above may apply for both integrated software and stand-alone software applications.

Further, the above process allows for integration of the materials with the software tests performed by the testing system. In particular, the multiple design levels allow for multiple levels and standards for testing, which give insights into completion rate and quality of various stakeholders and suppliers. This is accomplished at the multiple design levels which allow parsed materials to create software tests from human language. In particular, the plurality of design levels (which is associated with a plurality of languages) may be utilized (e.g., based on their syntax) by the testing system to create tests that can be used and reused over time and across different vehicles and vehicle variants. Thus, the OEM can monitor the software repositories and where things are being developed and run, as well as define the test for software not only internally but for the supplier as well. In other words, this allows for multi-vendor, multi-stakeholder vehicle software development.

Furthermore, the above process allows the introduction of non-conforming or unknown hardware, where the software tests can run to determine how far the hardware deviates from specification. In particular, the plurality of design levels may be utilized by the testing system to create an ontological software testing framework that uses rules or machine learning to identify hardware and determine its conforming or non-conforming nature with a vehicle's specification. From there, there can be a “provisional approval” for hardware that can run only under certain circumstances. In other words, the testing system may identify non-conforming hardware in a vehicle by using unit tests to adapt software to the limitations of the non-conforming hardware. For example, an ECU may not be compatible with high performance operation of a vehicle, but could operate the vehicle in “limp mode” for a limited period of time. This process could be supported by a rule based or ML process for adapting to hardware. Additionally, this system could be adapted to non-automotive applications including, for example, internet of things (IOT) connecting various devices in a house, such as air conditioning, heaters, batteries, solar panels, and smart controllers.

The above described tests may be automated between suppliers, which specify interoperability between suppliers. This enables the OEM to easily experiment on the tests by creating and simulating various scenarios for safety, quality and functionality, real-time progression of visualization of the testing system execution, multi-supplier and multi-variant, define specification, run the test, and do a delta impact analysis.

Upon performing operation S250, the method 200 may be ended or be terminated. Alternatively, method 200 may return to operation S210, such that the at least one processor may be configured to repeatedly perform, for at least a predetermined amount of time, the obtaining the plurality of vehicle design materials (at operation S210), the extracting the information (at operation S220), the storing the extracted information (at operation S230), the generating the vehicle software development plan (at operation S240), and/or the generating the GUI (at operation S250).

For instance, the at least one processor may continuously (or periodically) receive additional vehicle design materials, and then restart the obtaining the plurality of vehicle design materials (at operation S210), the extracting the information (at operation S220), the storing the extracted information (at operation S230), the generating the vehicle software development plan (at operation S240), and/or the generating the GUI (at operation S250).

FIG. 6 illustrates a block diagram of example components in a system 600, according to one or more example embodiments. The system 600 may correspond to the VSD system 120 in FIG. 1, thus the features associated with the VSD system 120 and the system 600 may be similarly applicable to each other, unless being explicitly described otherwise.

As illustrated in FIG. 6, the system 610 may include at least one bus 611, at least one processor 612, at least one memory 613, at least one storage component 614, at least one input component 615, at least one output component 616, and at least one communication interface 617.

It is contemplated that the system 610 may include more or less components than illustrated in FIG. 6, without departing from the scope of the present disclosure. For instance, in some embodiments, the system 610 may include a plurality of storage components 614, the input component 615 and the output component 616 may be implemented as a transceiver component, the memory 613 and storage component 614 may be implemented as a memory storage, and the like.

The bus 611 may be configured to facilitate or enable communications among the components of the system 610. Specifically, the bus 611 may communicatively couple the components to each other and provide a means for data transfer and flow of control signals between the components. The bus 611 may include one or more of: an internal bus, an address bus, a data bus, a control bus, a controller area network (CAN) bus, an Ethernet bus, a peripheral component interconnect express (PCIe) bus, and any other suitable type of bus that can be implemented in the system 610 to enable communication and coordination between the components within the system 610 in real-time (or near real-time).

The processor 612 may be implemented in hardware, firmware, or a combination of hardware and software, and may be configured to handle real-time (or near real-time) data processing and control of the control system 610. The processor 612 may include one or more of: a central processing unit (CPU), a graphics processing unit (GPU), a neural processing unit (NPU), a tensor processing unit (TPU), an accelerated processing unit (APU), a microprocessor, a microcontroller, a digital signal processor (DSP), a field-programmable gate array (FPGA), an application-specific integrated circuit (ASIC), and/or another type of processing or computing component that can be implemented in the system 610. In some implementations, the processor 612 may be capable of being programmed to perform one or more operations described herein. Further, the processor 612 may include a plurality of processing units, each of which is dedicated to performing a specific operation.

The memory 613 may include one or more mediums for storing temporary data, runtime variables, program instructions, and buffers required for the operations of the control system 610. The memory 613 may include one or more of: a flash memory, a read-only memory (ROM), a random-access memory (RAM), a dynamic or static storage device (e.g., a flash memory, a magnetic memory, and/or an optical memory), any other suitable type of memory that can be implemented in the system 610 to store information and/or instructions for use by the processor 612.

The storage component 614 may be configured to store non-volatile data, such as firmware, configuration settings, calibration data, information, and/or software related to the operation and use of the system 610. For example, the storage component 614 may include a hard disk (e.g., a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive.

According to example embodiments, the storage component 614 may be configured to store computer-readable or computer-executable instructions for implementing one or more operations of the system 610. The storage component 614 may provide the stored information to the memory 613 for the execution of the processor 612.

The input component 615 may include one or more input components that permit the system 610 to receive information, such as via user input (e.g., a touch screen display, a keyboard, a keypad, a mouse, a button, a switch, and/or a microphone). The output component 616 may include one or more output components that provide output information from the system 610 (e.g., a display, a speaker, a navigation device, one or more light-emitting diodes (LEDs), etc.) According to example embodiments, the input component 615 and/or the output component 616 may be optional and may be excluded from the system 610.

The at least one communication interface 617 may include a transceiver-like component (e.g., a transceiver and/or a separate receiver and transmitter) that enables the system 610 to communicate with other components (e.g., ECUs, user devices, etc.), such as via a wired connection, a wireless connection, or a combination of wired and wireless connections. For example, communication interface 617 may include a controller area network (CAN) bus interface, an Ethernet interface, an optical interface, a coaxial interface, an infrared interface, a radio frequency (RF) interface, a universal serial bus (USB) interface, a Wi-Fi interface, a cellular network interface, or the like.

According to one or more embodiments, the communication interface 617 may include at least one input/output (I/O) interface, at least one network interface, at least one storage interface, or the like, that enable the components 612-616 to communicate with other components. Further, the communication interface 617 may include one or more application programming interfaces (APIs) that allow the system 610 (or one or more components included therein) to communicate with one or more software applications (e.g., software application deployed in the ECUs, etc.)

Computer-executable instructions (e.g., software instructions, etc.) may be read into memory 613 and/or storage component 614 from another computer-readable medium or from another device (e.g., a remote server, an external storage, etc.) via, for example, the communication interface 617. When executed, the computer-executable instructions stored in memory 613 and/or storage component 614 may cause the processor 612 to perform one or more processes described herein. Additionally, or alternatively, hardwired circuitry may be used in place of or in combination with software instructions to perform one or more processes described herein. Thus, implementations described herein are not limited to any specific combination of hardware circuitry and software.

It is contemplated that features, advantages, and significances of example embodiments described hereinabove are merely a portion of the present disclosure, and are not intended to be exhaustive or to limit the scope of the present disclosure. Further descriptions of the features, components, configuration, operations, and implementations of example embodiments of the present disclosure, as well as the associated technical advantages and significances, are provided in the following.

It is understood that the specific order or hierarchy of blocks in the processes/flowcharts disclosed herein is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

Some embodiments may relate to a system, a method, and/or a computer-readable medium at any possible technical detail level of integration. Further, as described hereinabove, one or more of the above components described above may be implemented as instructions stored on a computer readable medium and executable by at least one processor (and/or may include at least one processor). The computer-readable medium may include a computer-readable non-transitory storage medium (or media) having computer-readable program instructions thereon for causing a processor (or processors) to carry out operations.

The computer readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object-oriented programming languages such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a SoC, a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or another device to cause a series of operational steps to be performed on the computer, other programmable apparatus or other device to produce a computer-implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer-readable media according to various embodiments. In this regard, each block in the flowchart or block diagrams may represent a module, segment, or portion of instructions, which comprises one or more executable instructions for implementing the specified logical function(s). The method, computer system, and computer-readable medium may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code-it being understood that software and hardware may be designed to implement the systems and/or methods based on the description herein.

What is claimed is:

1. A system comprising:
a memory storage storing computer-executable instructions; and
at least one processor communicatively coupled to the memory storage, wherein the at least one processor is configured to execute the instructions to:
obtain a plurality of vehicle design materials;
extract information from the plurality of vehicle design materials; and
generate a vehicle software development plan based on the extracted information,
wherein the vehicle software development plan comprises a plurality of design levels defining a plan for designing a vehicle software at a plurality of levels.

2. The system according to claim 1, wherein the at least one processor is configured to execute the instructions to extract information from the plurality of vehicle design materials by processing the plurality of vehicle design materials into an ontology of domain specific language.

3. The system according to claim 1, wherein the plurality of design levels comprises:
a first level defining a system of interest;
a second level defining a vehicle within the system of interest;
a third level defining a sub-system within the vehicle;
a fourth level defining hardware and software compositions within the sub-system;
a fifth level defining a component within the hardware and software compositions; and
a sixth level defining a sub-component within the component.

4. The system according to claim 1, wherein the plurality of vehicle design materials comprises a system requirement specification (SRS).

5. The system according to claim 1, wherein the at least one processor is configured to execute the instructions to store the extracted information in a single source of truth (SSOT) database.

6. The system according to claim 1, wherein the at least one processor is configured to execute the instructions to generate a graphical user interface (GUI) based on the vehicle software development plan, wherein the GUI shows interrelationships between a plurality of elements of the plurality of design levels across the plurality of design levels and interrelationships between the plurality of elements of the plurality of design levels within a respective level of the plurality of design levels.

7. The system according to claim 1, wherein the at least one processor is configured to execute the instructions to transmit data associated with the vehicle software development plan to a system for testing and validation of the vehicle software.

8. A method comprising:
obtaining a plurality of vehicle design materials;
extracting information from the plurality of vehicle design materials; and
generating a vehicle software development plan based on the extracted information,
wherein the vehicle software development plan comprises a plurality of design levels defining a plan for designing a vehicle software at a plurality of levels.

9. The method according to claim 8, wherein the extracting information from the plurality of vehicle design materials comprises processing the plurality of vehicle design materials into an ontology of domain specific language.

10. The method according to claim 8, wherein the plurality of design levels comprises:
a first level defining a system of interest;
a second level defining a vehicle within the system of interest;
a third level defining a sub-system within the vehicle;
a fourth level defining hardware and software compositions within the sub-system;
a fifth level defining a component within the hardware and software compositions; and
a sixth level defining a sub-component within the component.

11. The method according to claim 8, wherein the plurality of vehicle design materials comprises a system requirement specification (SRS).

12. The method according to claim 8, wherein the method further comprises storing the extracted information in a single source of truth (SSOT) database.

13. The method according to claim 8, wherein the method further comprises generating a graphical user interface (GUI) based on the vehicle software development plan, wherein the GUI shows interrelationships between a plurality of elements of the plurality of design levels across the plurality of design levels and interrelationships between the plurality of elements of the plurality of design levels within a respective level of the plurality of design levels.

14. The method according to claim 8, wherein the method further comprises transmitting data associated with the vehicle software development plan to a system for testing and validation of the vehicle software.

15. A non-transitory computer-readable recording medium having recorded thereon instructions executable by at least one processor to cause the at least one processor to perform a method comprising:
obtaining a plurality of vehicle design materials;
extracting information from the plurality of vehicle design materials; and
generating a vehicle software development plan based on the extracted information,
wherein the vehicle software development plan comprises a plurality of design levels defining a plan for designing a vehicle software at a plurality of levels.

16. The non-transitory computer-readable recording medium according to claim 15, wherein the extracting information from the plurality of vehicle design materials comprises processing the plurality of vehicle design materials into an ontology of domain specific language.

17. The non-transitory computer-readable recording medium according to claim 15, wherein the plurality of design levels comprises:
a first level defining a system of interest;
a second level defining a vehicle within the system of interest;
a third level defining a sub-system within the vehicle;
a fourth level defining hardware and software compositions within the sub-system;
a fifth level defining a component within the hardware and software compositions; and
a sixth level defining a sub-component within the component.

18. The non-transitory computer-readable recording medium according to claim 15, wherein the plurality of vehicle design materials comprises a system requirement specification (SRS).

19. The non-transitory computer-readable recording medium according to claim 15, wherein the method further comprises storing the extracted information in a single source of truth (SSOT) database.

20. The non-transitory computer-readable recording medium according to claim 15, wherein the method further comprises generating a graphical user interface (GUI) based on the vehicle software development plan, wherein the GUI shows interrelationships between a plurality of elements of the plurality of design levels across the plurality of design levels and interrelationships between the plurality of elements of the plurality of design levels within a respective level of the plurality of design levels.
